(19) United States
(12) Patent Application Publication
(10) Pub. No.: US 2024/0376603 A1
(43) Pub. Date: Nov. 14, 2024

(54) SUBSTRATE PROCESSING APPARATUS

(71) Applicant: Tokyo Electron Limited, Tokyo (JP)

(72) Inventor: Masato KADOBE, Tokyo (JP)

(21) Appl. No.: 18/648,828

(22) Filed: Apr. 29, 2024

(30) Foreign Application Priority Data
May 9, 2023 (JP) 2023-077234

(51) Int. Cl. C23C 16/46; C23C 16/44

(52) U.S. Cl. CPC C23C 16/46; C23C 16/4412

(57) ABSTRACT

A substrate processing apparatus, includes a processing container capable of accommodating a substrate holder configured to hold substrates; a pipe extending in a horizontal direction from a side wall of the processing container; and a heating mechanism provided around the processing container. The heating mechanism includes a first heating mechanism configured to cover a first region of the side wall of the processing container where the pipe is provided, and a second heating mechanism configured to cover a second region of the side wall of the processing container excluding the first region. The first heating mechanism has a first insertion hole through which the pipe is inserted, and the first heating mechanism is movable in the horizontal direction between a position where the pipe passes through the first insertion hole and a position where the pipe does not pass through the first insertion hole.

### CROSS-REFERENCE TO RELATED APPLICATION

This application is based upon and claims the benefit of priority from Japanese Patent Application No. 2023-077234, filed on May 9, 2023, the entire contents of which are incorporated herein by reference.

### TECHNICAL FIELD

The present disclosure relates to a substrate processing apparatus.

### BACKGROUND

There is known a vertical substrate processing apparatus that processes a plurality of substrates by supplying a processing gas into a processing container in a state in which a substrate holder holding the plurality of substrates is accommodated in the processing container. The substrate processing apparatus includes a plurality of gas supply pipes provided on the side portion of the processing container, and a heating part that covers the side peripheral portion of the processing container. The heating part is provided with a slit that extends from the lower end to the upper end of the heating part and allows the plurality of gas supply pipes to pass through.

### PRIOR ART DOCUMENT

### Patent Document

Patent Document 1: Japanese Patent Publication No. 5,645,718

### SUMMARY

According to one embodiment of the present disclosure, there is provided a substrate processing apparatus, includes a processing container capable of accommodating a substrate holder configured to hold substrates; a pipe extending in a horizontal direction from a side wall of the processing container; and a heating mechanism provided around the processing container. The heating mechanism includes a first heating mechanism configured to cover a first region of the side wall of the processing container where the pipe is provided, and a second heating mechanism configured to cover a second region of the side wall of the processing container excluding the first region. The first heating mechanism has a first insertion hole through which the pipe is inserted, and the first heating mechanism is movable in the horizontal direction between a position where the pipe passes through the first insertion hole and a position where the pipe does not pass through the first insertion hole.

### BRIEF DESCRIPTION OF DRAWINGS

The accompanying drawings, which are incorporated in and constitute a part of the specification, illustrate embodiments of the present disclosure, and together with the general description given above and the detailed description of the embodiments given below, serve to explain the principles of the present disclosure.

FIG. 1 is a vertical sectional view showing a substrate processing apparatus according to a first embodiment.

FIG. 2 is a horizontal sectional view showing the substrate processing apparatus according to the first embodiment.

FIG. 3 is a vertical sectional view showing the substrate processing apparatus according to the first embodiment.

FIG. 4 a is horizontal sectional view showing the substrate processing apparatus according to the first embodiment.

FIG. 5 is a perspective view showing an example of an injector.

FIG. 6 is a vertical sectional view showing a substrate processing apparatus according to a second embodiment.

FIG. 7 is a horizontal sectional view showing the substrate processing apparatus according to the second embodiment.

FIG. 8 is a vertical sectional view showing the substrate processing apparatus according to the second embodiment.

FIG. 9 is a horizontal sectional view showing the substrate processing apparatus according to the second embodiment.

FIG. 10 is a perspective view showing an example of an ejector.

FIG. 11 is a vertical sectional view showing a substrate processing apparatus according to a third embodiment.

FIG. 12 is a horizontal sectional view showing the substrate processing apparatus according to the third embodiment.

FIG. 13 is a vertical sectional view showing the substrate processing apparatus according to the third embodiment.

FIG. 14 is a horizontal sectional view showing the substrate processing apparatus according to the third embodiment.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

Non-limiting exemplary embodiments of the present disclosure will now be described with reference to the accompanying drawings. Throughout the attached drawings, the same or corresponding members or parts are designated by the same or corresponding reference numerals, and redundant descriptions will be omitted.

### First Embodiment

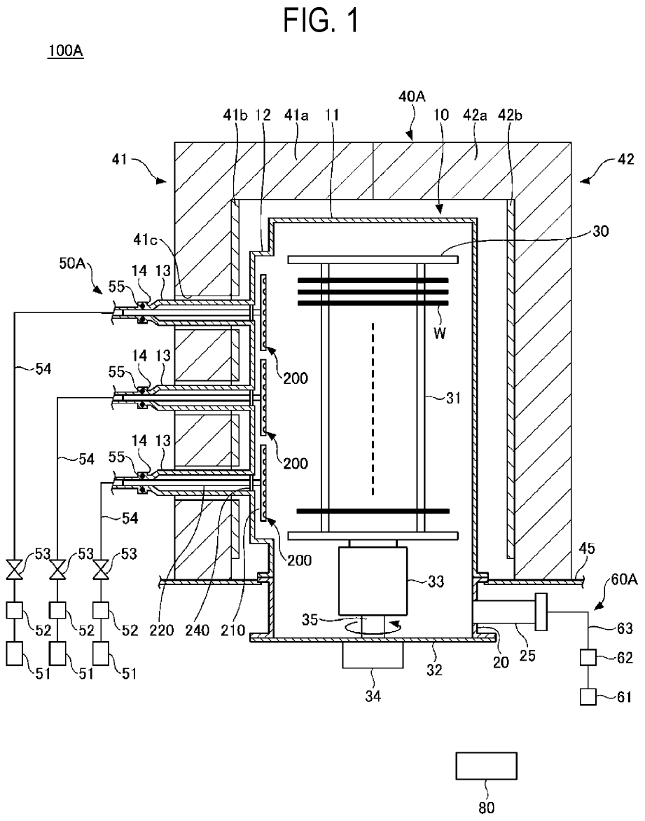

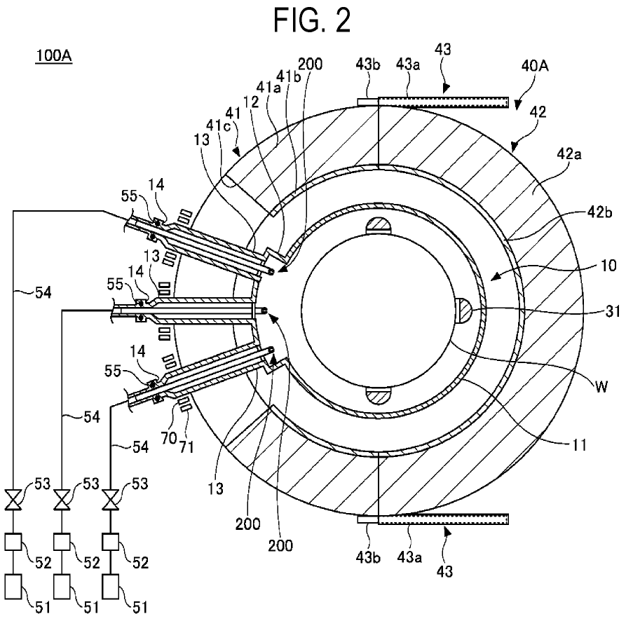

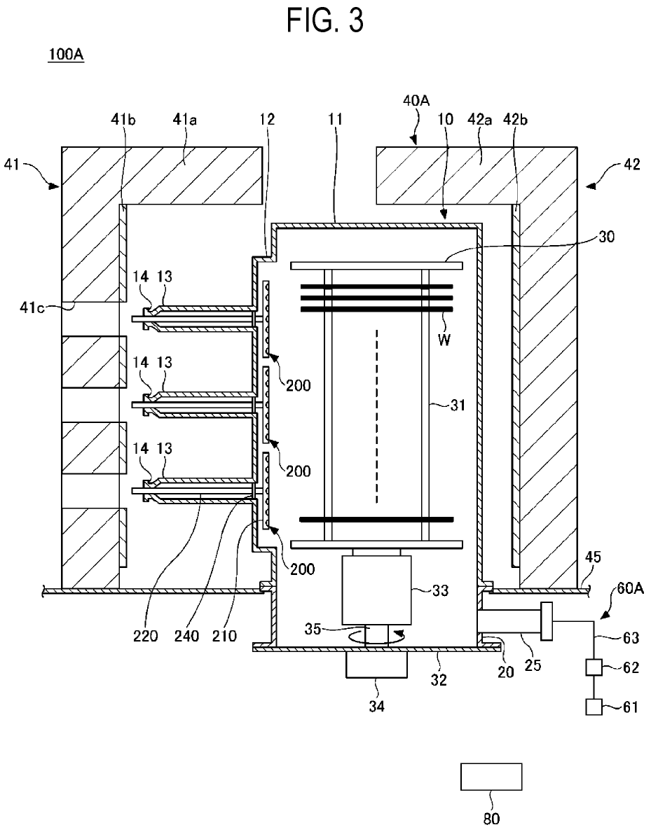

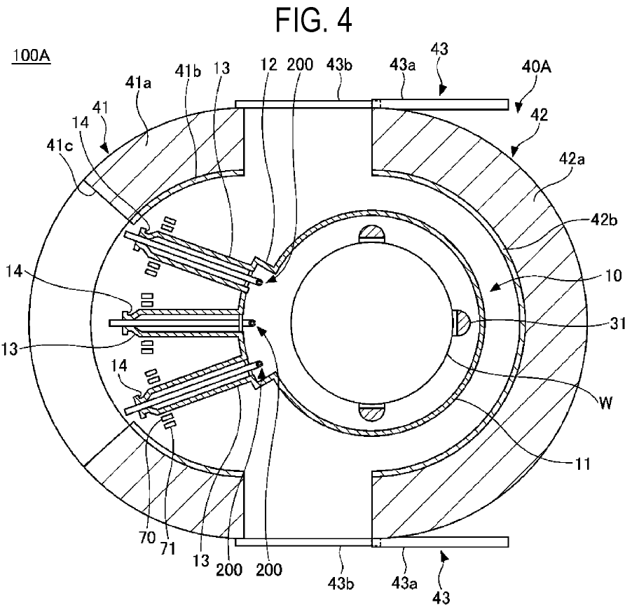

A substrate processing apparatus 100A according to a first embodiment will be described with reference to FIGS. 1 to 4. FIGS. 1 and 2 are views showing the substrate processing apparatus 100A in which a heating mechanism 40A is located at a processing position. FIGS. 3 and 4 are views showing the substrate processing apparatus 100A in which the heating mechanism 40A is located at a retracted position. FIGS. 1 and 3 are vertical sectional views of the substrate processing apparatus 100A. FIGS. 2 and 4 are horizontal sectional views of the substrate processing apparatus 100A.

The substrate processing apparatus 100A is a film-forming apparatus that forms a film on a substrate W by, for example, an atomic layer deposition (ALD) method by alternately supplying two or more types of processing gases. The substrate W is, for example, a semiconductor wafer. The substrate processing apparatus 100A includes a processing container 10.

The processing container 10 is made of quartz, for example. The processing container 10 includes a processing container body 11, a gas supply chamber 12, pipes (supply pipes) 13, and flanges 14.

The processing container body 11 has a cylindrical shape with a ceiling and an open bottom end.

The gas supply chamber 12 is formed such that a portion of the side surface of the processing container body 11 bulges outward along the length direction of the processing container body 11. The internal space of the gas supply chamber 12 is formed to communicate with the internal space of the processing container body 11.

One end of the pipe 13 communicates with the gas supply chamber 12, extends in the horizontal direction (radial direction of the processing container body 11), and the other end extends up to the outside of the heating mechanism 40A. For example, three pipes 13 are provided along the vertical direction, and three pipes 13 are provided along the circumferential direction of the processing container 10. However, the number of pipes 13 is not limited thereto. An injector 200 is arranged in the gas supply chamber 12 and the pipe 13.

The flange 14 is provided at the other end of the pipe 13.

A cylindrical metal flange portion 20 is airtightly connected to the lower end opening of the processing container 10 via a sealing member (not shown) such as an O-ring or the like. The flange portion 20 supports the lower end of the processing container 10.

A substrate holder 30 is inserted into the processing container 10 from below the flange portion 20. The substrate holder 30 holds a large number (e.g., 25 to 150) of substrates W in a horizontal posture in multiple stages. In the processing container 10, a large number of substrates W is accommodated substantially horizontally at intervals along the vertical direction. The substrate holder 30 is made of quartz, for example. The substrate holder 30 has three pillars 31. A plurality of grooves (not shown) are formed in each of the pillars 31 along the vertical direction. The substrate holder 30 supports a large number of substrates W using the grooves formed in the pillars 31.

A metal lid 32 is provided below the flange portion 20 to open and close the lower end opening of the flange portion 20. The lid 32 is configured to be movable up and down together with the substrate holder 30 by an elevating mechanism (not shown) such as a boat elevator or the like. A sealing member (not shown) is provided between the peripheral portion of the lid 32 and the lower end of the flange portion 20 to maintain airtightness within the processing container 10.

A heat insulator 33 made of quartz is provided between the substrate holder 30 and the lid 32. The rotation mechanism 34 rotates the substrate holder 30 and the heat insulator 33 about a vertical axis via a rotary shaft 35. The rotary shaft 35 airtightly passes through the lid 32 and connects the rotation mechanism 34 and the heat insulator 33.

The substrate holder 30 and the lid 32 are moved up and down together by an elevating mechanism, and are inserted into and removed from the inside of the processing container 10. The substrate holder 30 is rotated about a vertical axis by the rotation mechanism 34. The substrate W may be processed without rotating the substrate holder 30.

A heating mechanism 40A is provided around the processing container 10. The processing container 10, the flange portion 20, and the heating mechanism 40A are supported by a base plate 45 extending in the horizontal direction.

The heating mechanism 40A has a cylindrical shape with a ceiling. The heating mechanism 40A is configured to be vertically divisible into two parts. The heating mechanism 40A includes a supply heating mechanism 41, an exhaust heating mechanism 42, and slide rails 43.

The supply heating mechanism 41 includes a heat insulating member 41a and a heater 41b. The heat insulating member 41a has a semi-cylindrical shape with a ceiling and an open bottom end. The heat insulating member 41a covers a region of the side wall of the processing container 10 where the pipes 13 are provided. The heat insulating member 41a is provided with insertion holes 41c. The insertion holes 41c penetrate the heat insulating member 41a and extend in the horizontal direction (radial direction of the processing container 10). The pipes 13 are inserted through the insertion holes 41c. For example, three insertion holes 41c are provided along the vertical direction. Each insertion hole 41c has a rectangular shape, for example, when viewed from the radial direction of the processing container 10, and is provided so that three pipes 13 arranged side by side along the circumferential direction of the processing container 10 can be inserted therethrough. Alternatively, each insertion hole 41c may be provided so that one pipe 13 can be inserted therethrough. That is, the insertion hole 41c may be provided for each pipe 13. The heater 41b is arranged, for example, on the entire inner peripheral surface of the heat insulating member 41a where the insertion holes 41c are not provided. The heater 41b may be arranged only in a part of the inner peripheral surface of the heat insulating member 41a where the insertion holes 41c are not provided.

The supply heating mechanism 41 is movable in the horizontal direction between a processing position and a retracted position. The processing position is a position where the supply heating mechanism 41 is connected to the exhaust heating mechanism 42, as shown in FIGS. 1 and 2. At the processing position, the pipes 13 are inserted into the insertion holes 41c. At the processing position, each substrate W accommodated in the processing container 10 is processed. The retracted position is a position where the supply heating mechanism 41 is separated from the exhaust heating mechanism 42, as shown in FIGS. 3 and 4. At the retracted position, the pipes 13 are not inserted into the insertion holes 41c. At the retracted position, the processing container 10 is carried out from the inside of the heating mechanism 40A to the outside (below the heating mechanism 40A). At the retracted position, the processing container 10 is carried into the inside of the heating mechanism 40A from the outside of the heating mechanism 40A (below the heating mechanism 40A). At the retracted position, the pipes 13 are not inserted into the insertion holes 41c. Therefore, the pipes 13 and the supply heating mechanism 41 do not come into contact with each other when the processing container 10 is raised or lowered.

The exhaust heating mechanism 42 includes a heat insulating member 42a and a heater 42b. The heat insulating member 42a has a semi-cylindrical shape with a ceiling and an open bottom end. The heat insulating member 42a covers a region of the side wall of the processing container 10 where the pipes 13 are not provided. The heater 42b is arranged on the inner peripheral surface of the heat insulating member 42a. The exhaust heating mechanism 42 is fixed to the base plate 45.

The slide rails 43 guide the horizontal movement of the supply heating mechanism 41 relative to the exhaust heating mechanism 42. The slide rails 43 are provided, for example, in a pair on both sides of the heating mechanism 40A. Each slide rail 43 has an outer rail 43a and an inner rail 43b. The outer rail 43a is attached to the outer peripheral surface of the heat insulating member 42a. The inner rail 43b is attached to the outer peripheral surface of heat insulating member 41a. The inner rail 43b is slidable along the longitudinal direction of the outer rail 43a. When the slide rails 43 move the supply heating mechanism 41, the inner rail 43b slides along the longitudinal direction of the outer rail 43a so as to guide the horizontal movement of the supply heating mechanism 41 with respect to the exhaust heating mechanism 42. The slide rails 43 are an example of a guide mechanism.

The heating mechanism 40A heats the processing container 10 by radiant heat and thermal convection from the heaters 41b and 42b. The heating mechanism 40A controls the temperature of the processing container 10 to a desired temperature. Thus, the substrate inside the processing container 10 is heated by radiant heat and the like from the wall surface of the processing container 10. That is, the heating mechanism 40A heats the processing container 10 and the substrate W to a desired temperature.

Each of the supply heating mechanism 41 and the exhaust heating mechanism 42 may further include an outer skin and a water cooling jacket. The outer skin is provided so as to cover the outer periphery of the heat insulating member 41a or 42a. The outer skin maintains the shape of the heat insulating member 41a or 42a and reinforces the heat insulating member 41a or 42a. The outer skin is made of metal such as stainless steel, for example. The water cooling jacket is provided to cover the outer periphery of the outer skin. The water cooling jacket suppresses the influence of heat on the outside of the supply heating mechanism 41 or the exhaust heating mechanism 42.

The substrate processing apparatus 100A includes a gas supply 50A and a gas exhauster 60A.

The gas supply 50A supplies gases into the processing container 10. The gas supply 50A includes a gas supply chamber 12, pipes 13, injectors 200, gas supply sources 51, flow rate controllers 52, opening/closing valves 53, supply paths 54, injector heaters 70, and a water cooling jacket 71.

The gas supply source 51 supplies a gas. The flow rate controller 52 is, for example, a mass flow controller. The flow rate controller 52 adjusts the flow rate of the gas supplied from the gas supply source 51. The opening/closing valve 53 switches the supply and stop of the gas from the gas supply source 51 into the processing container 10. The supply path 54 connects the gas supply source 51 and the pipe 13. The flow rate controller 52 and the opening/closing valve 53 are arranged in the middle of the supply path 54. The supply path 54 and the pipe 13 are connected outside the heating mechanism 40A. The connection portion between the supply path 54 and the pipe 13 is airtightly connected via a sealing member 55 such as an O-ring or the like. The injector 200 is arranged across the gas supply chamber 12 and the pipe 13. The injector 200 receives a gas from the supply path 54 and discharges the supplied gas into the processing container 10. The injector heater 70 heats the pipe 13. The water cooling jacket 71 cools the pipe 13.

The gas exhauster 60A exhausts the gas from the inside of the processing container 10. The gas exhauster 60A includes an exhaust pipe 25, a vacuum pump 61, a pressure regulator 62, and an exhaust path 63. The exhaust pipe 25 is provided on the side wall of the flange portion 20. The gas inside the processing container 10 is exhausted to the outside of the processing container 10 by the gas exhauster 60A. The pressure inside the processing container 10 is controlled to a desired pressure by the pressure regulator 62.

The substrate processing apparatus 100A includes a controller 80. The controller 80 controls the operation of each part of the substrate processing apparatus 100A. The controller 80 may be, for example, a computer. A computer program for operating each part of the substrate processing apparatus 100A is stored in a non-transitory computer readable storage medium. The storage medium is, for example, a flexible disk, a compact disk, a hard disk, a flash memory, or a DVD.

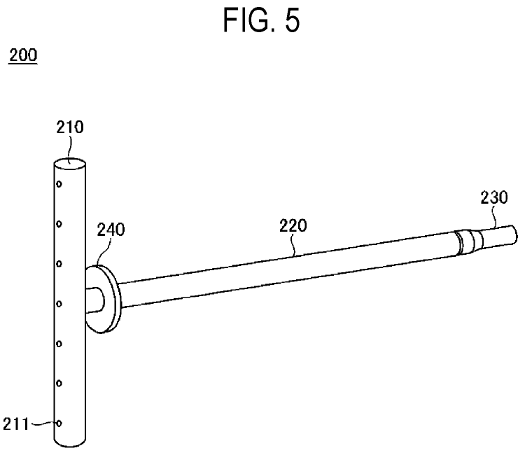

The injector 200 will be described with reference to FIG. 5. FIG. 5 is a perspective view showing an example of the injector 200. The injector 200 includes an injection portion 210, a transport portion 220, a supply portion 230, and a flange 240.

The injection portion 210 has an internal space through which a gas can flow, and has a cylindrical shape with a closed upper end and a closed lower end. When the injector 200 is installed in the substrate processing apparatus 100A, the injection portion 210 is arranged within the gas supply chamber 12 and extends in the height direction of the processing container 10. The injection portion 210 is provided with gas injection holes 211 that communicate with the internal space. A plurality of gas discharge holes 211 are provided in the injection portion 210 along the height direction of the processing container 10. Although the injection portion 210 has been described as having a cylindrical shape, the shape of the injection portion 210 is not limited thereto. For example, the injection portion 210 may have a cylindrical shape with an elliptical cross-sectional area, or a cylindrical shape with a polygonal cross-sectional area.

The transport portion 220 is a pipe having an internal space through which a gas can flow. The transport portion 220 has one end connected to the injection portion 210 so that a gas can flow therethrough, and the other end connected to the supply portion 230 so that a gas can flow therethrough. When the injector 200 is installed in the substrate processing apparatus 100A, the transport portion 220 is arranged inside the pipe 13. Although the transport portion 220 is illustrated as having a cylindrical shape, the shape of the transport portion 220 is not limited thereto. For example, the transport portion 220 may be a pipe with an elliptical cross-sectional area, or a pipe with a polygonal cross-sectional area.

The transport portion 220 is formed of, for example, a pipe having a straight shape (straight pipe). In this case, the gas supplied from the supply portion 230 can be quickly supplied to the injection portion 210. The transport portion 220 may be formed of a pipe having a spiral shape. In this case, it is possible to increase the residence time of the gas supplied from the supply portion 230 in the transport portion 220 until the gas is transported to the injection portion 210. Further, it is possible to increase the contact area between the inner circumferential surface of the transport portion 220 and the gas until the gas supplied from the supply portion 230 is transported to the injection portion 210. The transport portion 220 may be formed of a plurality of thin pipes connecting the supply portion 230 and the injection portion 210. In this case, it is possible to increase the contact area between the transport portion 220 and the gas.

The supply portion 230 is a connection portion connected to the supply path 54. A gas is supplied to the supply portion 230 from the supply path 54.

The flange 240 is provided on the outer peripheral surface of the transport portion 220 and is formed to have a diameter approximately equal to (slightly smaller than) the inner diameter of the pipe 13. When the injector 200 is installed in the substrate processing apparatus 100A, the flange 240 is inserted into the pipe 13. Thus, the injector 200 is located in place, blocking the space between the inner circumferential surface of the pipe 13 and the outer circumferential surface of the transport portion 220, from the inner spaces of the processing container body 11 and the gas supply chamber 12. This suppresses a high-temperature gas in the internal spaces of the processing container body 11 and the gas supply chamber 12 from flowing into the space between the inner circumferential surface of the pipe 13 and the outer circumferential surface of the transport portion 220.

In this way, the gas supplied from the gas supply source 51 flows through the supply portion 230, the transport portion 220, and the injection portion 210 in the named order from the supply path 54, and is supplied into the processing container 10 from the gas injection holes 211.

As described above, the substrate processing apparatus 100A includes the processing container 10 capable of accommodating the substrate holder 30 that holds the substrates W, the pipes 13 extending horizontally from the side wall of the processing container 10, and the heating mechanism 40A provided around the processing container 10. The heating mechanism 40A includes the supply heating mechanism 41 that covers the region of the side wall of the processing container 10 where the pipes 13 are provided, and the exhaust heating mechanism 42 that covers the region of the side wall of the processing container 10 where the pipes 13 are not provided. The supply heating mechanism 41 has insertion holes 41c through which the pipes 13 are inserted. The supply heating mechanism 41 is movable in the horizontal direction between the processing position where the pipes 13 are inserted through the insertion holes 41c and the retracted position where the pipes 13 are not inserted through the insertion holes 41c. In this case, by providing the insertion holes 41c at least at the positions corresponding to the positions where the pipes 13 are provided, the processing container 10 can be carried in and out of the heating mechanism 40A. Therefore, it is possible to reduce the ratio of the insertion holes 41c to the entire heat insulating member 4la. The region in which the insertion holes 41c are provided easily dissipate heat because there is no heat insulating member 41a. In the embodiment, as described above, it is possible to reduce the ratio of the insertion holes 41c to the entire heat insulating member 41a. Therefore, it is possible to suppress heat dissipation to the outside of the processing container 10. As a result, the in-plane temperature uniformity of the substrate W and the temperature uniformity between the substrates W can be improved while reducing power consumption. Furthermore, since the area of the inner peripheral surface of the heat insulating member 41a becomes larger, it is possible to arrange a larger number of heaters 41b.

Further, according to the substrate processing apparatus 100A, the gases are supplied into the processing container 10 through the pipes 13 extending horizontally from the side wall of the processing container 10. In this case, the distance (time) in which the gases flow within the processing container 10 becomes shorter, which makes it easier to supply the substrate W with gases having a temperature different from the substrate temperature.

Further, according to the substrate processing apparatus 100A, each of the pipes 13 is connected to each supply path 54, and each supply path 54 is provided with the gas supply source 51 and the flow rate regulator 52. In this case, the type of gas can be changed in the vertical and horizontal directions, and the flow rate of the gas can be adjusted.

Further, according to the substrate processing apparatus 100A, each of the pipes 13 is provided with the individual injector heater 70 and the water cooling jacket 71. In this case, the temperature of the gas can be adjusted in the vertical and horizontal directions.

In the above-described embodiment, there has been described the case where the heating mechanism 40A can be vertically divided into two parts. However, the present disclosure is not limited thereto. For example, the heating mechanism 40A may be vertically divisible into three or more parts. In this case, as in the above-described embodiment, the heating mechanism covering at least the region where the pipes 13 are provided may be movable along the horizontal direction. For example, the heating mechanism 40A may be divided into a cylindrical upper part with a ceiling located above the position where the uppermost pipe 13 is provided, and a cylindrical lower part located below the upper part, and only the lower part may be vertically divided into two or more parts. For example, the heating mechanism 40A may have a cylindrical body portion and a ceiling portion that closes the ceiling of the cylindrical body portion, and only the cylindrical body portion may be vertically divided into two or more parts.

### Second Embodiment

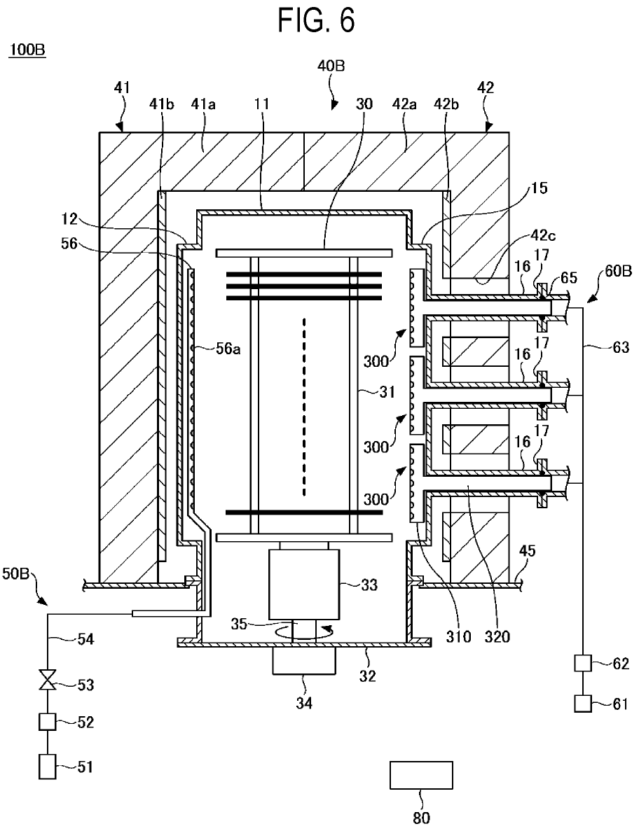

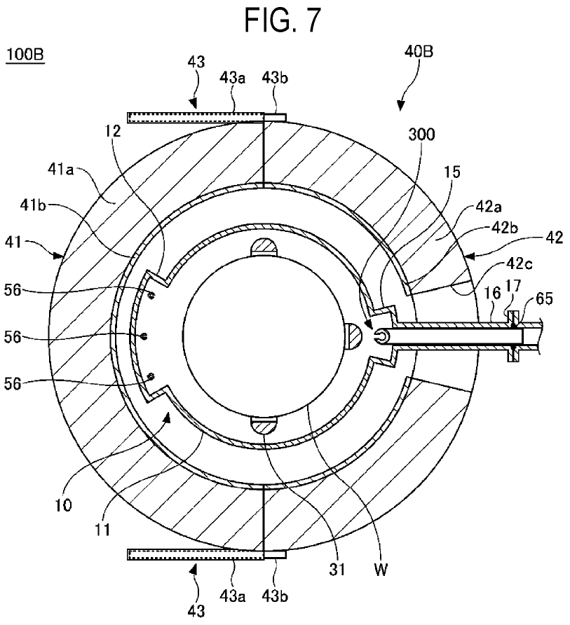

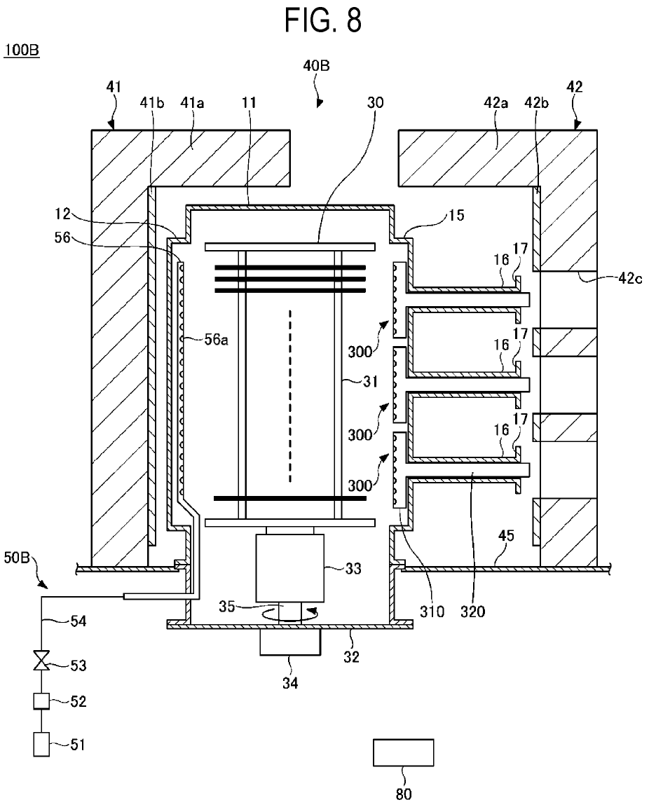

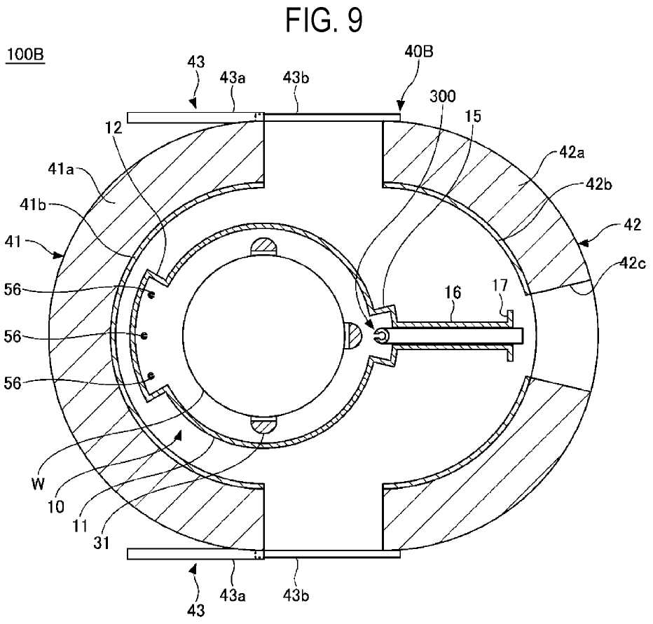

A substrate processing apparatus 100B according to a second embodiment will be described with reference to FIGS. 6 to 9. FIGS. 6 and 7 are views showing the substrate processing apparatus 100B in which a heating mechanism 40B is located at the processing position. FIGS. 8 and 9 are views showing the substrate processing apparatus 100B in which the heating mechanism 40B is located at the retracted position. FIGS. 6 and 8 are vertical sectional views of the substrate processing apparatus 100B. FIGS. 7 and 9 are horizontal sectional views of the substrate processing apparatus 100B.

The substrate processing apparatus 100B includes a heating mechanism 40B, a gas supply 50B, and a gas exhauster 60B in place of the heating mechanism 40A, the gas supply 50A, and the gas exhauster 60A in the substrate processing apparatus 100A. Other configurations are the same as those of the substrate processing apparatus 100A. Hereinafter, a description will be given focusing on the configurations different from the configurations of the substrate processing apparatus 100A.

The processing container 10 includes a processing container body 11, a gas supply chamber 12, a gas exhaust chamber 15, pipes (exhaust side pipes) 16, and flanges 17.

The processing container body 11 has a cylindrical shape with a ceiling and an open bottom end.

The gas supply chamber 12 is formed such that a part of the side surface of the processing container body 11 bulges outward along the length direction of the processing container body 11. The internal space of the gas supply chamber 12 is formed to communicate with the internal space of the processing container body 11.

The gas exhaust chamber 15 is formed such that a part of the side surface of the processing container body 11 bulges outward along the length direction of the processing container body 11. The internal space of the gas exhaust chamber 15 is formed to communicate with the internal space of the processing container body 11.

The pipe 16 has one end communicating with the gas exhaust chamber 15 and extends in the horizontal direction (radial direction of the processing container 10) to penetrate the side surface of the heating mechanism 40B. The pipe 16 has the other end extending to the outside of the heating mechanism 40B. For example, three pipes 16 are provided along the vertical direction. However, the number of pipes 16 is not limited thereto. Injectors 300 are arranged in the gas exhaust chamber 15 and the pipes 16.

The flange 17 is provided at the other end of the pipe 16.

The heating mechanism 40B has a cylindrical shape with a ceiling. The heating mechanism 40B is configured to be vertically divisible into two parts. The heating mechanism 40B includes a supply heating mechanism 41, an exhaust heating mechanism 42, and slide rails 43.

The supply heating mechanism 41 includes a heat insulating member 41a and a heater 41b. The heat insulating member 41a has a semi-cylindrical shape with a ceiling and an open bottom end. The heat insulating member 41a covers a region of the side wall of the processing container 10 where the pipes 16 are not provided. The heater 41b is arranged on the inner peripheral surface of the heat insulating member 41a. The supply heating mechanism 41 is fixed to the base plate 45.

The exhaust heating mechanism 42 includes a heat insulating member 42a and a heater 42b. The heat insulating member 42a has a semi-cylindrical shape with a ceiling and an open bottom end. The heat insulating member 42a covers a region of the side wall of the processing container 10 where the pipes 16 are provided. The heat insulating member 42a is provided with insertion holes 42c. The insertion holes 42c penetrate the heat insulating member 42a and extend in the horizontal direction (radial direction of the processing container 10). The pipes 16 are inserted through the insertion holes 42c. For example, three insertion holes 42c are provided along the vertical direction. Each insertion hole 42c has, for example, a circular shape when viewed from the radial direction of the processing container 10. Each insertion hole 42c is provided so that one pipe 16 can be inserted therethrough. That is, the insertion hole 42c is provided for each pipe 16. However, the insertion hole 42c may be formed in a rectangular shape with the vertical direction serving as a longitudinal direction and the circumferential direction of the processing container 10 serving as a transverse direction, so that three pipes 16 arranged side by side along the vertical direction can be inserted therethrough. The heater 42b is arranged, for example, on the entire inner peripheral surface of the heat insulating member 42a where the insertion holes 42c are not provided. The heater 42b may be arranged only in a part of the inner peripheral surface of the heat insulating member 42a where the insertion holes 42c are not provided.

The exhaust heating mechanism 42 is movable in the horizontal direction between the processing position and the retracted position. The processing position is a position where the exhaust heating mechanism 42 is connected to the supply heating mechanism 41, as shown in FIGS. 6 and 7. At the processing position, the pipes 16 are inserted into the insertion holes 42c. At the processing position, each substrate W accommodated in the processing container 10 is processed. The retracted position is a position where the exhaust heating mechanism 42 is separated from the supply heating mechanism 41, as shown in FIGS. 8 and 9. At the retracted position, the pipes 16 are not inserted into the insertion holes 42c. At the retracted position, the processing container 10 is carried out from the inside of the heating mechanism 40B to the outside (below the heating mechanism 40B). At the retracted position, the processing container 10 is carried into the inside of the heating mechanism 40B from the outside of the heating mechanism 40B (below the heating mechanism 40B). At the retracted position, the pipes 16 are not inserted into the insertion holes 42c. Therefore, the pipes 16 and the exhaust heating mechanism 42 do not come into contact with each other when the processing container 10 is raised or lowered.

The slide rails 43 guide the movement of the exhaust heating mechanism 42 relative to the supply heating mechanism 41 in the horizontal direction. The slide rails 43 are provided, for example, in a pair on both sides of the heating mechanism 40B. Each slide rail 43 has an outer rail 43a and an inner rail 43b. The outer rail 43a is attached to the outer peripheral surface of the heat insulating member 41a. The inner rail 43b is attached to the outer peripheral surface of the heat insulating member 42a. The inner rail 43b is slidable along the longitudinal direction of the outer rail 43a. When the slide rails 43 move the exhaust heating mechanism 42, the inner rail 43b slides along the longitudinal direction of the outer rail 43a to guide the horizontal movement of the exhaust heating mechanism 42 with respect to the supply heating mechanism 41. The slide rails 43 are an example of a guide mechanism.

The substrate processing apparatus 100B includes a gas supply 50B and a gas exhauster 60B.

The gas supply 50B supplies a gas into the processing container 10. The gas supply 50B includes a gas supply source 51, a flow rate controller 52, an opening/closing valve 53, a supply path 54, and a gas supply pipe 56.

The gas supply source 51 supplies a gas. The flow rate controller 52 is, for example, a mass flow controller. The flow rate controller 52 adjusts the flow rate of the gas supplied from the gas supply source 51. The opening/closing valve 53 switches the supply and stop of the gas from the gas supply source 51 into the processing container 10. The supply path 54 connects the gas supply source 51 and the gas supply pipe 56. The flow rate controller 52 and the opening/closing valve 53 are arranged in the middle of the supply path 54. The gas supply pipe 56 is inserted into the processing container 10 from the flange portion 20 and arranged within the gas supply chamber 12. A plurality of injection portions 56a are formed in the gas supply pipe 56 along the height direction.

The gas exhauster 60B exhausts the gas from the inside of the processing container 10. The gas exhauster 60B includes a gas exhaust chamber 15, pipes 16, injectors 300, a vacuum pump 61, a pressure regulator 62, and an exhaust path 63. The gas inside the processing container 10 is exhausted to the outside of the processing container 10 by the gas exhauster 60B. The pressure inside the processing container 10 is controlled to a desired pressure by the pressure regulator 62. The pipes 16 and the exhaust path 63 are connected outside the heating mechanism 40B. The connection portion between the pipe 16 and the exhaust path 63 is airtightly connected via a sealing member 65 such as an O-ring or the like. The injectors 300 are arranged across the gas exhaust chamber 15 and the pipes 16. When a plurality of pipes 16 are provided, the vacuum pump 61 and the pressure regulator 62 may be provided by merging the downstream sides of the exhaust paths 63. Alternatively, the vacuum pump 61, the pressure regulator 62, and the exhaust path 63 may be provided for each pipe 16.

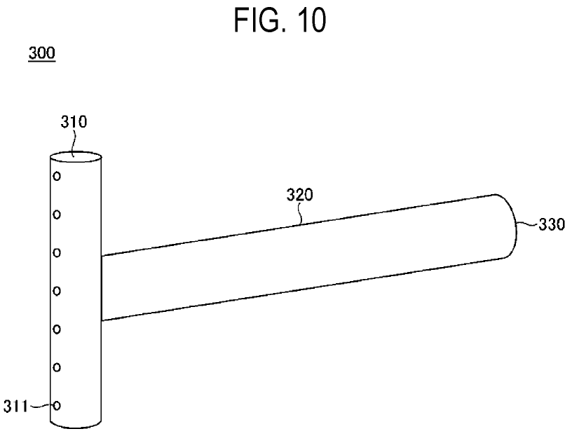

The ejector 300 will be described with reference to FIG. 10. FIG. 10 is a perspective view showing an example of the ejector 300. The ejector 300 includes a suction portion 310, a transport portion 320, and a discharge portion 330.

The suction portion 310 has an internal space through which a gas can flow, and has a cylindrical shape with a closed upper end and a closed lower end. When the ejector 300 is installed in the substrate processing apparatus 100B, the suction portion 310 is arranged within the gas exhaust chamber 15 and extends in the height direction of the processing container 10. The suction portion 310 is provided with gas suction holes 311 that communicate with the internal space. A plurality of gas suction holes 311 are provided in the suction portion 310 along the height direction of the processing container 10. Although the suction portion 310 has been described as having a cylindrical shape, the shape of the suction portion 310 is not limited thereto. For example, the suction portion 310 may have a cylindrical shape with an elliptical cross-sectional area, or a cylindrical shape with a polygonal cross-sectional area.

The transport portion 320 is a pipe having an internal space through which a gas can flow. One end of the transport portion 320 is connected to the suction portion 310 so that a gas can flow therethrough, and the other end is connected to the discharge portion 330 so that a gas can flow therethrough. When the ejector 300 is installed in the substrate processing apparatus 100B, the transport portion 320 is arranged inside the pipe 16. Although the transport portion 320 is illustrated as having a cylindrical shape, the shape of the transport portion 320 is not limited thereto. For example, the transport portion 320 may be a pipe having an elliptical cross-sectional area, or a pipe having a polygonal cross-sectional area.

The transport portion 320 is formed of, for example, a pipe having a straight shape (straight pipe). In this case, the gas sucked through the gas suction holes 311 of the suction portion 310 can be quickly exhausted to the discharge portion 330.

The discharge portion 330 is a connection portion connected to the exhaust path 63. The discharge portion 330 exhausts a gas to the exhaust path 63.

In this way, the gas in the processing container 10 flows from the gas suction holes 311 through the suction portion 310, the transport portion 320, and the discharge portion 330 in the named order, and is exhausted to the exhaust path 63. Although the injectors 300 are installed in the second embodiment, the ejectors 300 may not be provided. In this case, the exhaust resistance can be reduced, and therefore the gas in the processing container 10 can be more quickly exhausted from the pipe 16.

As described above, the substrate processing apparatus 100B includes the processing container 10 capable of accommodating the substrate holder 30 that holds the substrates W, the pipes 16 extending horizontally from the side wall of the processing container 10, and the heating mechanism 40B provided around the processing container 10. The heating mechanism 40B includes the exhaust heating mechanism 42 that covers a region of the side wall of the processing container 10 where the pipes 16 are provided, and the supply heating mechanism 41 that covers a region of the side wall of the processing container 10 where the pipes 16 are not provided. The exhaust heating mechanism 42 has the insertion holes 42c through which the pipes 16 are inserted. The exhaust heating mechanism 42 is movable in the horizontal direction between the processing position where the pipes 16 pass through the insertion holes 42c and the retracted position where the pipes 16 do not pass through the insertion holes 42c. In this case, by providing the insertion holes 42c at least at the positions corresponding to the positions where the pipes 16 are provided, the processing container 10 can be carried in and out of the heating mechanism 40B. Therefore, it is possible to reduce the ratio of the insertion holes 42c to the entire heat insulating member 42a. The region where the insertion holes 42c are provided easily dissipates heat because there is no heat insulating member 42a. In the embodiment, as described above, it is possible to reduce the ratio of the insertion holes 42c to the entire heat insulating member 42a. Therefore, it is possible to suppress heat dissipation to the outside of the processing container 10. As a result, the in-plane temperature uniformity of the substrate W and the temperature uniformity between the substrates W can be improved while reducing power consumption. Furthermore, since the area of the inner peripheral surface of the heat insulating member 42a becomes larger, it is possible to arrange a larger number of heaters 42b.

### Third Embodiment

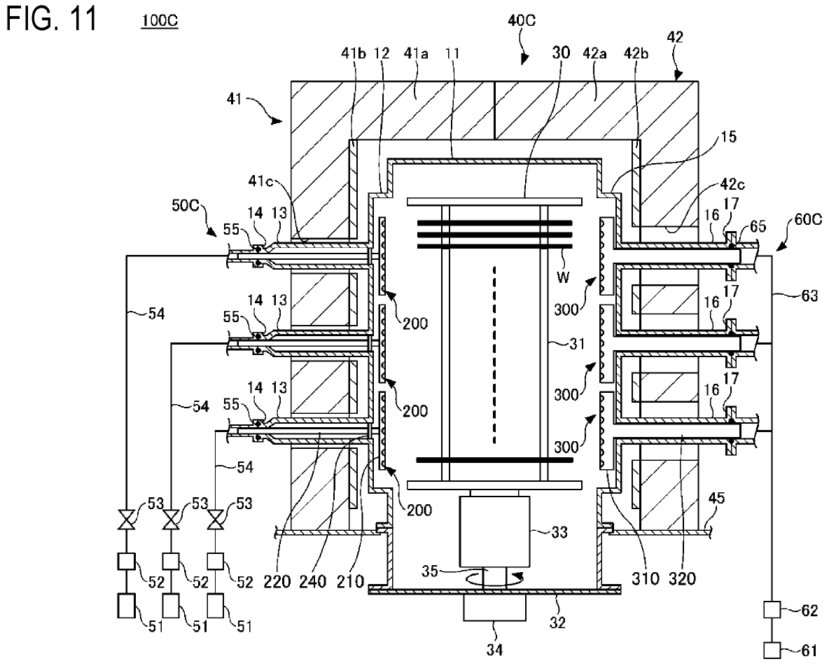

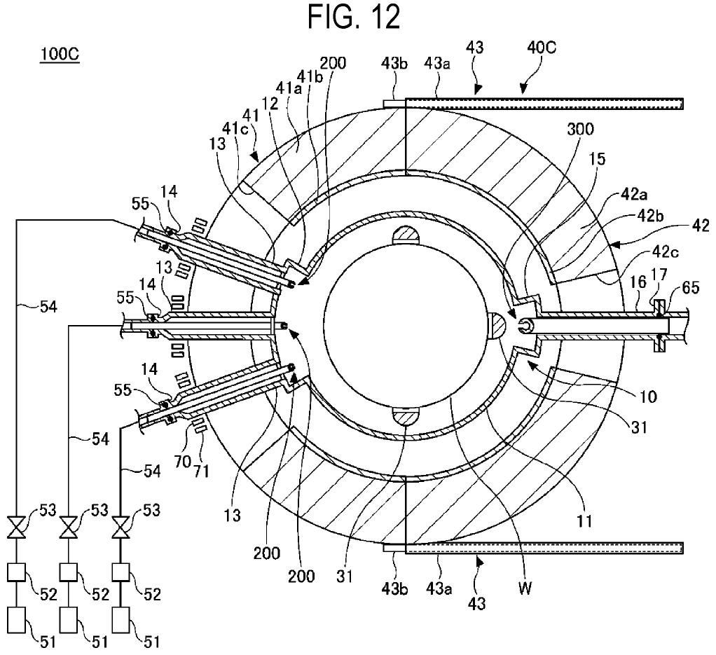

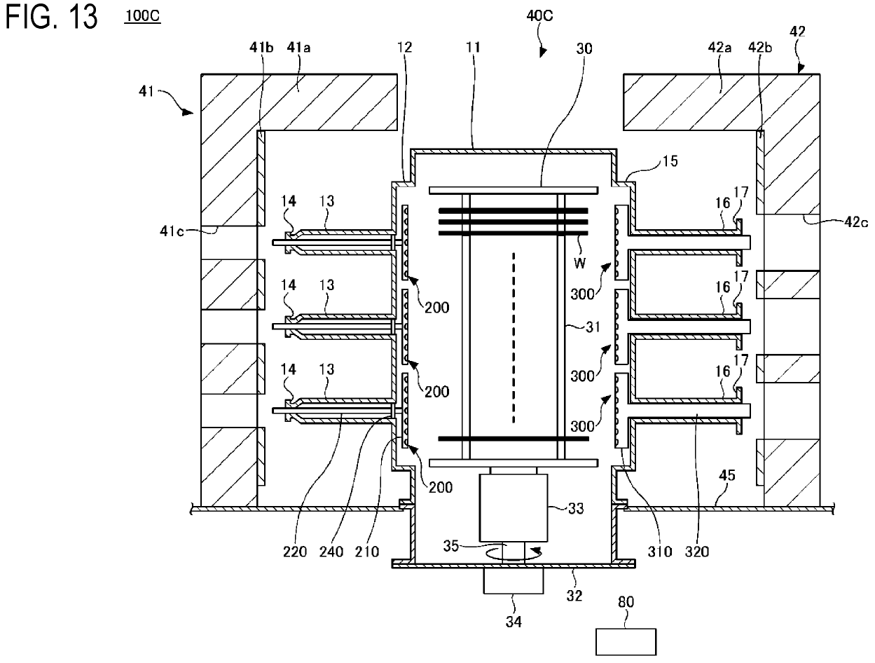

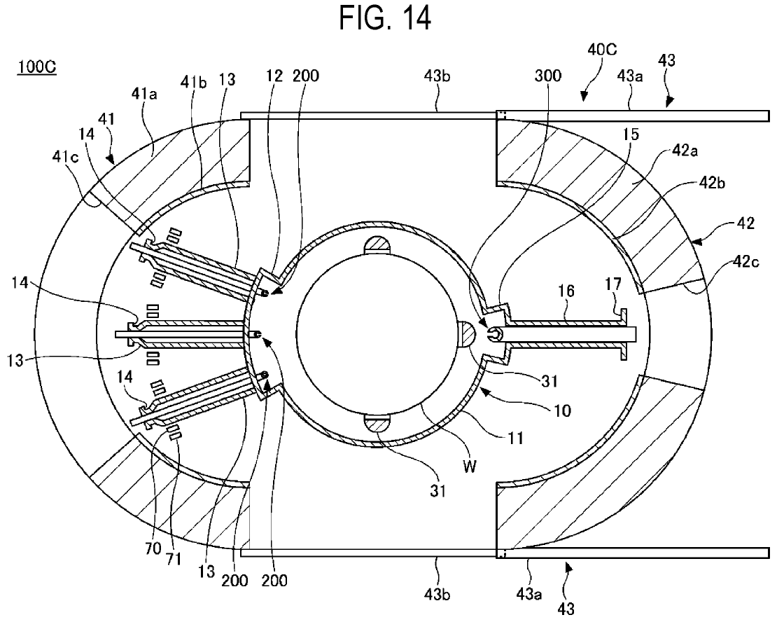

A substrate processing apparatus 100C according to a third embodiment will be described with reference to FIGS. 11 to 14. FIGS. 11 and 12 are views showing the substrate processing apparatus 100C in which the heating mechanism 40C is located at the processing position. FIGS. 13 and 14 are views showing the substrate processing apparatus 100C in which the heating mechanism 40C is located at the retracted position. FIGS. 11 and 13 are vertical sectional views of the substrate processing apparatus 100C. FIGS. 12 and 14 are horizontal sectional views of the substrate processing apparatus 100C.

The substrate processing apparatus 100C includes a heating mechanism 40C, a gas supply 50C, and a gas exhauster 60C in place of the heating mechanism 40A, the gas supply 50A, and the gas exhauster 60A in the substrate processing apparatus 100A. Other configurations are the same as the configurations of the substrate processing apparatus 100A. The gas supply 50C has the same configuration as the gas supply 50A. The gas exhauster 60C has the same configuration as the gas exhauster 60B.

The heating mechanism 40C has a cylindrical shape with a ceiling. The heating mechanism 40C is configured to be vertically divisible into two parts. The heating mechanism 40C includes a supply heating mechanism 41, an exhaust heating mechanism 42, and slide rails 43.

The supply heating mechanism 41 includes a heat insulating member 41a and a heater 41b. The heat insulating member 41a has a semi-cylindrical shape with a ceiling and an open bottom end. The heat insulating member 41a covers a region of the side wall of the processing container 10 where the pipes 13 are provided. The heat insulating member 41a is provided with insertion holes 41c. The insertion holes 41c penetrate the heat insulating member 41a and extend in the horizontal direction (radial direction of the processing container 10). The pipes 13 are inserted through the insertion holes 41c. For example, three insertion holes 41c are provided along the vertical direction. Each insertion hole 41c has, for example, a rectangular shape when viewed from the radial direction of the processing container 10, and is provided so that three pipes 13 arranged side by side along the circumferential direction of the processing container 10 can be inserted therethrough. However, each insertion hole 41c may be provided so that one pipe 13 can be inserted therethrough. That is, the insertion hole 41c may be provided for each pipe 13. The heater 41b is arranged, for example, on the entire inner peripheral surface of the heat insulating member 41a where the insertion holes 41c are not provided. The heater 41b may be arranged only in a part of the inner peripheral surface of the heat insulating member 41a where the insertion holes 41c are not provided.

The supply heating mechanism 41 is movable in the horizontal direction between a processing position and a retracted position. The processing position is a position where the supply heating mechanism 41 is connected to the exhaust heating mechanism 42, as shown in FIGS. 11 and 12. At the processing position, the pipes 13 are inserted into the insertion holes 41c. At the processing position, each substrate W accommodated in the processing container 10 is processed. The retracted position is a position where the supply heating mechanism 41 is separated from the exhaust heating mechanism 42, as shown in FIGS. 13 and 14. At the retracted position, the pipes 13 are not inserted into the insertion holes 41c. At the retracted position, the processing container 10 is carried out from the inside of the heating mechanism 40C to the outside (below the heating mechanism 40C). At the retracted position, the processing container 10 is carried into the inside of the heating mechanism 40C from the outside of the heating mechanism 40C (below the heating mechanism 40C). At the retracted position, the pipes 13 are not inserted into the insertion holes 41c. Therefore, the pipe 13 and the supply heating mechanism 41 do not come into contact with each other when the processing container 10 is raised or lowered.

The exhaust heating mechanism 42 includes a heat insulating member 42a and a heater 42b. The heat insulating member 42a has a semi-cylindrical shape with a ceiling and an open bottom end. The heat insulating member 42a covers a region of the side wall of the processing container 10 where the pipes 16 are provided. The heat insulating member 42a is provided with insertion holes 42c. The insertion holes 42c penetrate the heat insulating member 42a and extends in the horizontal direction (radial direction of the processing container 10). The pipes 16 are inserted through the insertion holes 42c. For example, three insertion holes 42c are provided along the vertical direction. Each insertion hole 42c has, for example, a circular shape when viewed from the radial direction of the processing container 10. Each insertion hole 42c is provided so that one pipe 16 can be inserted therethrough. That is, the insertion hole 42c is provided for each pipe 16. Alternatively, the insertion hole 42c may be formed in a rectangular shape with the vertical direction serving as a longitudinal direction and the circumferential direction of the processing container 10 serving as a transverse direction, so that the three pipes 16 arranged side by side along the vertical direction can be inserted therethrough. The heater 42b is arranged, for example, on the entire inner peripheral surface of the heat insulating member 42a where the insertion holes 42c are not provided. The heater 42b may be arranged only in a part of the inner peripheral surface of the heat insulating member 42a where the insertion holes 42c are not provided.

The exhaust heating mechanism 42 is movable in the horizontal direction between the processing position and the retracted position. The processing position is a position where the exhaust heating mechanism 42 is connected to the supply heating mechanism 41, as shown in FIGS. 11 and 12. At the processing position, the pipes 16 are inserted into the insertion holes 42c. At the processing position, each substrate W accommodated in the processing container 10 is processed. The retracted position is a position where the exhaust heating mechanism 42 is separated from the supply heating mechanism 41, as shown in FIGS. 13 and 14. At the retracted position, the pipes 16 are not inserted into the insertion holes 42c. At the retracted position, the processing container 10 is carried out from the inside of the heating mechanism 40C to the outside (below the heating mechanism 40C). At the retracted position, the processing container 10 is carried into the inside of the heating mechanism 40C from the outside of the heating mechanism 40C (below the heating mechanism 40C). At the retracted position, the pipes 16 are not inserted into the insertion holes 42c. Therefore, the pipes 16 and the exhaust heating mechanism 42 do not come into contact with each other when the processing container 10 is raised or lowered.

The slide rails 43 guide horizontal movement of the supply heating mechanism 41 relative to the exhaust heating mechanism 42 and horizontal movement of the exhaust heating mechanism 42 relative to the supply heating mechanism 41. The slide rails 43 are provided in a pair on both sides of the heating mechanism 40C, for example. Each slide rail 43 has an outer rail 43a and an inner rail 43b. The outer rail 43a is attached to the outer peripheral surface of the heat insulating member 42a. The inner rail 43b is attached to the outer peripheral surface of the heat insulating member 4la. The inner rail 43b is slidable along the longitudinal direction of the outer rail 43a. When the slide rails 43 move the supply heating mechanism 41 and the exhaust heating mechanism 42, the inner rail 43b slides along the longitudinal direction of the outer rail 43a and guides the horizontal movement of the supply heating mechanism 41 and the exhaust heating mechanism 42. The slide rails 43 are an example of a guide mechanism.

As described above, the substrate processing apparatus 100C includes the processing container 10 capable of accommodating the substrate holder 30 that holds the substrates W, the pipes 13 and 16 extending horizontally from the side wall of the processing container 10, and the heating mechanism 40C provided around the processing container 10. The heating mechanism 40C includes the supply heating mechanism 41 that covers a region of the side wall of the processing container 10 where the pipes 13 are provided, and the exhaust heating mechanism 42 that covers a region of the side wall of the processing container 10 where the pipes 16 are provided. The supply heating mechanism 41 has the insertion holes 41c through which the pipes 13 are inserted. The supply heating mechanism 41 is movable in the horizontal direction between the processing position where the pipes 13 are inserted through the insertion holes 41c and the retracted position where the pipes 13 are not inserted through the insertion holes 41c. The exhaust heating mechanism 42 has the insertion holes 42c through which the pipes 16 are inserted. The exhaust heating mechanism 42 is movable in the horizontal direction between the processing position where the pipes 16 pass through the insertion holes 42c and the retracted position where the pipes 16 do not pass through the insertion holes 42c. In this case, by providing the insertion holes 41c at least at the positions corresponding to the positions where the pipes 13 are provided and the insertion holes 42c at the positions corresponding to the positions where the pipes 16 are provided, the processing container 10 can be carried into and out of the heating mechanism 40C. Therefore, it is possible to reduce the ratio of the insertion holes 41c and 42c to the entire heat insulating members 41a and 42a. The regions where the insertion holes 41c and 42c are provided can easily dissipate heat because there are no heat insulating members 41a and 42a. In the embodiment, as described above, it is possible to reduce the ratio of the insertion holes 41c and 42c to the entire heat insulating members 41a and 42a. Therefore, it is possible to suppress heat dissipation to the outside of the processing container 10. As a result, the in-plane temperature uniformity of the substrate W and the temperature uniformity between the substrates W can be improved while reducing power consumption. Furthermore, since the area of the inner peripheral surface of the heat insulating members 41a, 42a becomes larger, it is possible to arrange a larger number of heaters 41b and 42b.

The embodiments disclosed herein should be considered to be exemplary in all respects and not limitative. The embodiments described above may be omitted, replaced, or modified in various forms without departing from the scope and spirit of the appended claims.

According to the present disclosure in some embodiments, it is possible to suppress heat dissipation to the outside of a processing container.

While certain embodiments have been described, these embodiments have been presented by way of example only, and are not intended to limit the scope of the disclosures. Indeed, the embodiments described herein may be embodied in a variety of other forms. Furthermore, various omissions, substitutions, and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A substrate processing apparatus, comprising:
a processing container capable of accommodating a substrate holder configured to hold substrates;
a pipe extending in a horizontal direction from a side wall of the processing container; and
a heating mechanism provided around the processing container,
wherein the heating mechanism includes a first heating mechanism configured to cover a first region of the side wall of the processing container where the pipe is provided, and a second heating mechanism configured to cover a second region of the side wall of the processing container excluding the first region,
the first heating mechanism has a first insertion hole through which the pipe is inserted, and
the first heating mechanism is movable in the horizontal direction between a position where the pipe passes through the first insertion hole and a position where the pipe does not pass through the first insertion hole.

2. The apparatus of claim 1, wherein the heating mechanism includes a guide mechanism configured to guide movement of the first heating mechanism.

3. The apparatus of claim 1, wherein the pipe is a supply pipe configured to supply a gas into the processing container.

4. The apparatus of claim 3, further comprising:
an exhaust pipe extending in the horizontal direction from the side wall of the processing container and configured to exhaust the gas in the processing container,
wherein the exhaust pipe is provided in the second region,
the second heating mechanism has a second insertion hole through which the exhaust pipe is inserted, and
the second heating mechanism is movable in the horizontal direction between a position where the exhaust pipe passes through the second insertion hole and a position where the exhaust pipe does not pass through the second insertion hole.

5. The apparatus of claim 1, wherein the pipe is an exhaust pipe configured to exhaust a gas in the processing container.
